(19) United States
(12) Patent Application Publication
(10) Pub. No.: US 2026/0202496 A1
(43) Pub. Date: Jul. 16, 2026

(54) MEMS BASED ELECTRO-OPTICAL MRI COIL TUNER

(71) Applicants: BOGAZICI UNIVERSITESI, Istanbul (TR); IHSAN DOGRAMACI BILKENT UNIVERSITESI, Ankara (TR)

(72) Inventors: Arda Deniz YALCINKAYA, Istanbul (TR); Ergin ATALAR, Ankara (TR)

(21) Appl. No.: 19/136,786

(22) PCT Filed: Dec. 7, 2023
(86) PCT No.: PCT/TR2023/051493

§ 371 Date: Jun. 6, 2025

(30) Foreign Application Priority Data
Dec. 9, 2022 (TR) 2022/018948

(51) Int. Cl. G01R 33/36

(52) U.S. Cl. CPC G01R 33/3657; G01R 33/3692

(57) ABSTRACT

A microsystem compatible with magnetic resonance imaging (MRI) based on the detuning of the radiofrequency (RF) coil by driving the metallic micro-electromechanical system with the help of direct current induced by the photodetector illuminated by a fibre optic cable and by using it as a switch.

### TECHNICAL FIELD OF THE INVENTION

The invention relates to the detuning of the transmitting and receiving radiofrequency coils of a magnetic resonance imaging device depending on the magnetic field.

The invention particularly relates to a microsystem compatible with magnetic resonance imaging (MRI) based on the detuning of the radiofrequency (RF) coil by driving the metallic micro-electromechanical system with the help of direct current induced by the photodetector illuminated by a fibre optic cable and by using it as a switch.

### STATE OF THE ART

Magnetic resonance imaging devices are devices used especially in the field of medicine to view the body structures of living things in full detail, based on the orientation of atoms in the direction of the magnetic field under a magnetic field and oscillating at a certain frequency, and enabling the formation of images from radio waves reflected back from the oscillating atoms at a certain frequency with the application of radio waves.

In magnetic resonance imaging devices, powerful magnets are used to create the interaction necessary for atoms to move. Radio waves sent to vibrating atoms under the influence of strong magnets cause the atoms to oscillate and emit radio waves. These emanations are combined with the help of a computer to create moving or still three-dimensional images.

Magnetic resonance imaging device generally consists of three basic parts: magnet, cabinet, image processing and operator computer. The magnet varies according to the types of devices to create a stable magnetic field. Radio waves are sent into the magnetic field provided by the magnet. The cabinet also serves as an intermediate element between the image processing computer and the magnet data flow, carrying components such as helium pump control cards, power supplies and control cards, radio frequency and feeding cards that ensure the continuity of the magnet. Image processing and operator computers are the components that create the images of the magnetic resonance imaging device. The data received from the radio frequency coils are transferred to the image processing computer via the transmission line, and the image processing computer interprets the incoming signals with the signal processors and transfers the data to the operator computer. The operator computer is the component that enables the incoming data to be obtained in the desired format.

Radiofrequency coils are devices that transmit radio waves used in the application of radio waves in magnetic resonance imaging devices or receive radio waves coming from living things. Since these devices propagate waves at high amplitude, the receiving coil must be disabled during the operation of the transmitting coil, and the transmitting coil must be disabled during the operation of the receiving coil.

Radiofrequency coils are usually achieved by electrically activating a PIN diode or field-effect transistor (FET) to deafen the radio waves in the sequence in which they emit. The activation signal used for deafening is transmitted to the PIN diode or field effect transistor through metallic cables with high electrical conductivity. The high direct current, magnetic flux density and high amplitude radio frequency magnetic flux density of the magnetic resonance imaging device can be transferred on conductive materials and cause problems such as mechanical excitation and heating. For this reason, additional insulation is required in environments where magnetic resonance imaging devices are used.

The patent file numbered “U.S. Pat. No. 10,613,166B2” is in the state of the art was examined. In the invention that is the subject of the application, an apparatus comprising an adjustment circuit electrically connected to the receiver coil and a micro-electromechanical system switch electrically connected in parallel to the adjustment circuit, and a control circuit that enables the switch to be opened and closed within a specified time, to separate a receiver coil from a transmitter coil, is mentioned.

The patent document numbered “CN112540335A” in the state of the art was reviewed. In the invention that is the subject of the application, a device that detunes an antenna coil of a magnetic resonance tomography device and the working method of this device are mentioned.

The patent document numbered “CN113093073A” in the state of the art was reviewed. In the invention that is the subject of the application, flexible magnetic resonance radio frequency coil structure comprising a tuning capacitor of the radio frequency resonant circuit, a tuning circuit, including a signal feed point capacitor connected in series through a conductor and including detuner, input end balance, a transmission line, a parallel capacitor, tuning capacitor and signal feed point capacitor is mentioned.

The patent document numbered “US2020096583A1” in the state of the art was reviewed. In the invention that is the subject of the application, a magnetic resonance receiver coil containing a resonator, a first conductive element and a second conductive element for use in a magnetic resonance imaging system is mentioned.

### THE AIM OF THE INVENTION

The most important aim of the invention is to enable an electromagnetic micro-electromechanical system (MEMS) based bridge, which is switched by an optical signal transmitted over a fibre optic cable, to detune the receiver coil by adding a parallel coil to the resonance tank. In this way, effective detuning is achieved and the interaction between the receiver and transmitter coils is eliminated.

Another aim of the invention is to enable switching by using fibre optic cables instead of conductive cables. Thus, it prevents heating and image distortion problems that may occur during the operation of the parts of the magnetic resonance imaging device.

Another aim of the invention is that the electromagnetic micro-electromechanical system switch does not consume direct current power.

Another aim of the invention is to ensure that the electromagnetic micro-electromechanical system switch has high conductivity. Thus, it eliminates the interaction between the receiver and transmitter coils by providing effective detuning.

Another aim of the invention is that the electromagnetic micro-electromechanical system switch does not require high polarisation current.

### DESCRIPTION OF THE DRAWINGS

FIG. 1 is the drawing showing the magnetic resonance receiver coil detuning system that is the subject of the invention.

FIG. 2 is the drawing showing the current voltage characteristic between the anode-cathode terminals of the photo sensor that is the subject of the invention.

FIG. 3 is the drawing showing the perspective view of the magnetic resonance receiver coil detuning system that is the subject of the invention.

FIG. 4 is the drawing showing the frequency graph of the magnetic resonance receiver coil detuning system that is the subject of the invention.

### REFERENCE NUMBERS

100. Micro-Electromechanical System Based Electro-Optical Magnetic Resonance Imaging Coil Detuner
110. Tuning Coil
111. First Micro-Electromechanical System Switch Movable Upper Electrode
112. Second Micro-Electromechanical System Switch Movable Upper Electrode
113. Third Micro-Electromechanical System Switch Movable Right Electrode
120. Tuning Capacitor
121. Micro-Electromechanical System Switch Common Fixed Lower Electrode
122. Fourth Micro-Electromechanical System Switch Fixed Left Electrode
130. Light Source
140. Fibre Optic Cable
150. Photo Sensor
151. Photo Detector Short Circuit Current
160. Radiofrequency Coil
170. First Node
171. Second Node
180. Substrate
V_{D}: Voltage Between Anode and Cathode
I_{D}: Direct Current
A: Detuning Signal

### DESCRIPTION OF THE INVENTION

The invention is a micro-electromechanical system (MEMS) based electro-optical magnetic resonance imaging (MRI) coil detuner (100), comprising tuning coil (110), first micro-electromechanical system switch movable upper electrode (111), second micro-electromechanical system switch movable upper electrode (112), third micro-electromechanical system switch movable right electrode (113), tuning capacitor (120), micro-electromechanical system switch common fixed lower electrode (121), fourth micro-electromechanical system switch fixed left electrode (122), light source (130), fiber optic cable (140), photo sensor (150), photo sensor short circuit current (151), radiofrequency coil (160), first node (170) and second node (171) providing electrical connection and substrate (180).

The first micro-electromechanical system switch movable upper electrode (111), the second micro-electromechanical system switch movable upper electrode (112), the third micro-electromechanical system switch movable right electrode (113), the micro-electromechanical system switch common fixed lower electrode (121) and the fourth micro-electromechanical system switch fixed left electrode (122) form the radiofrequency MEMS bridge and the radiofrequency MEMS bridge is located on the insulating substrate (180).

The light source (130) is positioned in front of the fibre optic cable (140) and provides the necessary light for the fibre optic cable (140) to transmit. In this way, the detuning signal (A) is produced optically and transferred to the fibre optic cable (140). The fibre optic cable (140) optically transmits the detuning signal (A) it receives to the photo sensor (150) located behind it. The photo sensor (150) comprises the circuit line located between the anode and cathode terminals and is conductive for direct current (DC). When a light beam higher than the band energy of the semiconductor photodetector (150) is incident on the anode and cathode terminals and circuit line contained in the photodetector (150), the photodetector short circuit current (151) moves from the cathode to the anode. Thus, it converts the detuning signal (A) optically transmitted through the fibre optic cable (140) into electric current.

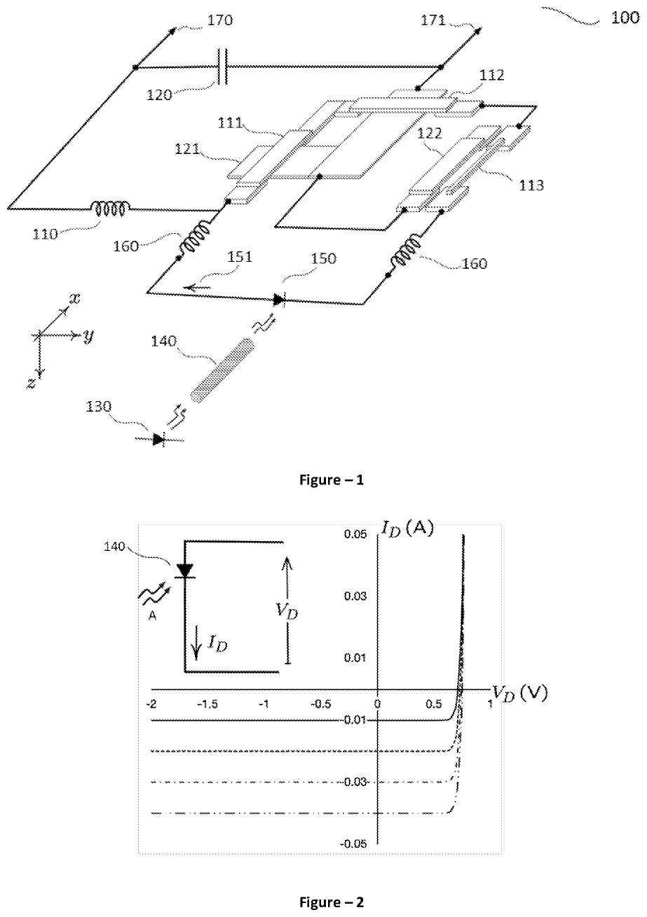

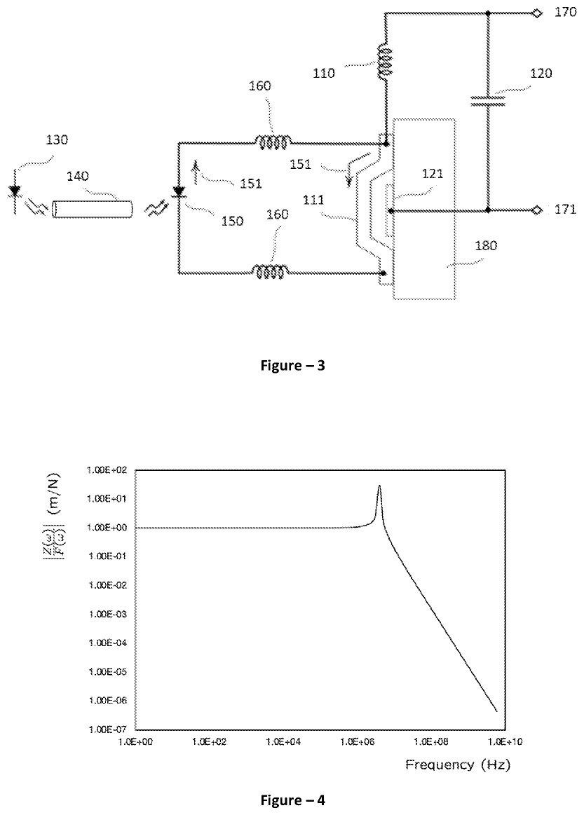

FIG. 2 shows the current voltage graph between the anode-cathode terminals of the photo sensor (150). When the voltage (V_{D}) between the anode and cathode contained in the photo sensor (150) is zero, the current coming out of the anode terminal of the photo sensor (150) returns to the cathode terminal of the photo sensor (150) via the radiofrequency coil (160), the first micro-electromechanical system switch movable upper electrode (111), the second micro-electromechanical system switch movable upper electrode (112), the third micro-electromechanical system switch movable right electrode (113) and finally the radiofrequency coil (160), respectively. The radiofrequency coil (160), first micro-electromechanical system switch movable upper electrode (111), the second micro-electromechanical system switch movable upper electrode (112) and the third micro-electromechanical system switch movable right electrode (113) show short circuit resistance for direct current (I_{D}) since they are metallic circuit elements. Photo sensor short circuit current (151) cannot travel from the line between the tuning coil (110) and the tuning capacitor (120) or from the line between the tuning coil (110) and the first node (170), or from the line between the tuning coil, tuning capacitor (120) and the second node (171) due to the capacitor and high impedance on the serial line. Photo sensor short circuit current (I_{DT}) (151) proceeds in the x coordinate plane on the first micro-electromechanical system switch movable upper electrode (111) in line with the coordinate system given in FIG. 1. The micro-electromechanical system-based electro-optical magnetic resonance imaging coil tuner (100) system creates the electromagnetic excitation force in accordance with the Lorentz principle by multiplying the photodetector short circuit current (I_{DT}) (151) and the magnetic flux density when the magnetic field (B₀) is positioned in the direction of the y coordinate plane. Equation 1 gives the electromagnetic excitation force of the micro-electromechanical system-based electro-optical magnetic resonance imaging coil tuner (100) system positioned in this way.

$${F}_{m} \vec{{e}_{z}} = ( {I}_{D T} \vec{{e}_{x}} \times {B}_{0} \vec{{e}_{y}} ) L \qquad Equation l$$

In Equation 1 above, L is the length of the bridge structure formed by the first micro-electromechanical system switch movable upper electrode (111) and the second micro-electromechanical system switch movable upper electrode (112) in the x coordinate plane, and Fₘ is the amplitude of the drive force in the z coordinate plane.

The micro-electromechanical system switch common fixed lower electrode (121) located just below the first micro-electromechanical system switch movable upper electrode (111) is connected to the coil that is desired to be detuned and the tuning capacitor (120) via the second node (171). The electromagnetic drive force given in Equation 1 is calculated by Equation 2 as the amount of mechanical displacement (Δz) depending on the spring constant (k_{z1}) in the z coordinate plane of the elastic bridge structure formed by the first micro-electromechanical system switch movable upper electrode (111) and the second micro-electromechanical system switch movable upper electrode (112),

$$Δ z \vec{{e}_{z}} = \frac{{F}_{m} \vec{{e}_{z}}}{{k}_{z 1}} \qquad Equation 2$$

When the displacement becomes equal to the height of the air gap separating the first micro-electromechanical system switch movable upper electrode (111) and the micro-electromechanical system switch common fixed lower electrode (121), the first micro-electromechanical system switch movable upper electrode (111) is short-circuited to the micro-electromechanical system switch common fixed lower electrode (121). Thus, the tuning coil (110) and the tuning capacitor (120) are connected to each other in parallel via the first micro-electromechanical system switch movable upper electrode (111) and the micro-electromechanical system switch common fixed lower electrode (121). By means of this connection, the tuning coil (110) and the tuning capacitor (120) are connected in parallel to the receiver coil that is connected to the first node (170) and second node (171) terminals that are desired to be detuned.

When the direction of the magnetic field is towards the negative x direction of the coordinate plane given in FIG. 1, the direct current (I_{D}) and the magnetic field are parallel to each other. For this reason, the moving upper electrode (111) of the first micro-electromechanical system switch cannot be induced by electromagnetic force and direct current (I_{D}) moves towards the second micro-electromechanical system switch movable upper electrode (112), which is connected to the continuation of the first micro-electromechanical system switch movable upper electrode (111). In this case, the direct current (I_{D}) is equal to the component of the photodetector short-circuit current (I_{DT}) (151) on the y coordinate plane. Thus, the electromagnetic drive force of the micro-electromechanical system-based electro-optical magnetic resonance imaging coil tuner (100) system given in Equation 1 is calculated as in Equation 3.

$${F}_{m} \vec{{e}_{z}} = - ( {I}_{DT} \vec{{e}_{y}} \times {B}_{0} \vec{{e}_{x}} ) L \qquad Equation 3$$

The first micro-electromechanical system switch movable upper electrode (111) and the second micro-electromechanical system switch movable upper electrode (112) are manufactured from the same material and have identical geometric shapes. The mechanical displacement (Δz) depending on the spring constant (k_{z2}) in the z coordinate plane of the second micro-electromechanical system switch movable upper electrode (112) of the electromagnetic drive force given in Equation 3 is calculated with Equation 4.

$$Δ z \vec{{e}_{z}} = \frac{{F}_{m} \vec{{e}_{z}}}{{k}_{z 2}} \qquad Equation 4$$

In this case, when the displacement becomes equal to the height of the air gap separating the second micro-electromechanical system switch movable upper electrode (112) and the micro-electromechanical system switch common fixed lower electrode (121), the second micro-electromechanical system switch movable upper electrode (112) is short-circuited to the micro-electromechanical system switch common fixed lower electrode (121). In this way, the tuning coil (110) and the tuning capacitor (120) are connected in parallel to each other via the second micro-electromechanical system switch movable upper electrode (112) and the micro-electromechanical system switch common fixed lower electrode (121). By means of this connection, the tuning coil (110) and the tuning capacitor (120) are connected in parallel to the receiver coil that is connected to the first node (170) and second node (171) terminals that are desired to be detuned.

When the direction of the magnetic field is towards the negative z direction of the coordinate plane given in FIG. 1, the electromagnetic forces induced by direct current (I_{D}) and magnetic field on the first micro-electromechanical system switch movable upper electrode (111) and the second micro-electromechanical system switch movable upper electrode (112) are in the +y-direction and −x-direction, respectively, and does not provide the necessary mechanical displacement to create a short circuit with the first micro-electromechanical system switch movable upper electrode (111). The direct current (I_{D}) is transmitted to the third micro-electromechanical system switch movable right electrode (113), which is connected in series on the first micro-electromechanical system switch movable upper electrode (111) and the second micro-electromechanical system switch movable upper electrode (112). In this case, the direct current (I_{D}) vector is equal to the component of the photodetector short circuit current (I_{DT}) (151) on the negative z coordinate plane. The magnetic field drive force in the −z-coordinate direction is calculated with Equation 5.

$$- {F}_{m} \vec{{e}_{y}} = \to ( - {I}_{D T} \vec{{e}_{x}} \times - {B}_{0} \vec{{e}_{z}} ) L \qquad Equation 5$$

In Equation 5 above, L is the length of the third micro-electromechanical system key moving right electron (113) in the x coordinate plane, and Fₘ is the amplitude of the driving force in the −y-coordinate plane. The fourth micro-electromechanical system switch fixed left electrode (122) located right next to the third micro-electromechanical system switch moving right electrode (113) is connected to the coil that is desired to be detuned and the tuning capacitor (120) via the second node (171). The mechanical displacement (Δy) of the electromagnetic driving force given in Equation 5 is calculated with Equation 6 depending on the spring constant (k_{y}) in the y coordinate plane of the third micro-electromechanical system switch movable right electrode (113).

$$- Δ y \vec{{e}_{y}} = \frac{- {F}_{m} \vec{{e}_{y}}}{{k}_{y}} \qquad Equation 6$$

When the displacement in this case is equal to the height of the air gap separating the third micro-electromechanical system switch movable right electrode (113) and the fourth micro-electromechanical system switch fixed left electrode (122), the third micro-electromechanical system switch movable right electrode (113), the micro-electromechanical system switch common fixed lower electrode (121) and the fourth micro-electromechanical system switch fixed left electrode (122) are short-circuited.

In this way, the tuning coil (110) and the tuning capacitor (120) are connected to each other in parallel via the third micro-electromechanical system switch moving right electrode (113), the micro-electromechanical system switch common fixed lower electrode (121) and the fourth micro-electromechanical system switch fixed left electrode (122). By means of this connection, the tuning coil (110) and the tuning capacitor (120) are connected in parallel to the receiver coil that is connected to the first node (170) and second node (171) terminals that are desired to be detuned.

The electrical component that causes the receiver coil to detune is the photodetector short circuit current (151). This current is the short circuit current that occurs due to optical excitation in the photo sensor (150). The detuning signal (A) is a pulse sequence formed by carrying the light source (130) over the fibre optic cable (140) and falling on the photo sensor (150). Assuming that the light source (130) can be modulated at high speeds of 10 MHz and above, that there is a negligible time delay in its transmission over the fibre optic cable (140), and that the optical-electrical conversion occurring in the photo sensor (150) is 100 ns and below, the time response of the micro-electromechanical system switch common fixed lower electrode (121), the second micro-electromechanical system switch movable upper electrode (112) and the third micro-electromechanical system switch movable right electrode (113) determine the tuning changing speed of the receiver coil.

The bridge structure formed by the first micro-electromechanical system switch movable upper electrode (111) and the second micro-electromechanical system switch movable upper electrode (112) is a conductive, micro-mechanical structure that is mechanically fixed on a base at both ends and released in a way that leaves a certain air gap for the plate below or next to which it will conduct transmission. When a force is induced on this structure, the bridge structure behaves as a mass-damping-spring system. If the magnetic field induced on the bridge structure in the z coordinate plane direction is considered as the driving force, the response of the mass-damping-spring system is calculated with Equation 7.

$${F}_{m} ( t ) = {m}_{e} \frac{d {v}_{z} ( t )}{d t} + {d}_{e} \cdot {v}_{z} ( t ) + {k}_{e z} \int {v}_{z} ( t ) d t \qquad Equation 7$$

In Equation 7, v_{z}(t) denotes the velocity occurring on the structure in the z coordinate plane, mₑ denotes the effective mass of the structure, dₑ denotes the effective damping parameter, and k_{ez} denotes the effective spring constant in the z coordinate plane. Equation 7 is expressed as Equation 8 as the Laplace transform in the complex frequency domain.

$${F}_{m} ( s ) = {V}_{z} ( s ) ( {m}_{e} s + {d}_{e} + \frac{{k}_{e z}}{s} ) \qquad Equation 8$$

The interaction between speed and force in Equation 8 is given in Equation 9.

$$\frac{{V}_{z} ( s )}{{F}_{m} ( s )} = \frac{\frac{s}{{m}_{e}}}{{s}^{2} + \frac{{d}_{e}}{{m}_{e}} s + \frac{{k}_{e z}}{{m}_{e}}} \qquad Equation 9$$

The displacement of the bridge in the z coordinate plane is expressed by Equation 10.

$$Z ( s ) = \frac{{V}_{z} ( s )}{s} \qquad Equation 10$$

The Laplace transformation of the response of the mass-damping-spring system of the magnetic field driving force with the displacement of the bridge in the z coordinate plane is included in Equation 11.

$$\frac{Z ( s )}{{F}_{m} ( s )} = \frac{\frac{1}{{m}_{e}}}{{s}^{2} + \frac{{d}_{e}}{{m}_{e}} s + \frac{{k}_{e z}}{{m}_{e}}} = \frac{1}{{k}_{ez}} \frac{{ω}_{m}^{2}}{{s}^{2} + \frac{{ω}_{m}}{Q} s + {ω}_{m}^{2}} \qquad Equation 11$$

In Equation 11, ωₘ=\sqrt{k_{ez}/mₑ} represents the basic mechanical resonance frequency of the bridge and Q=\sqrt{(k_{ez}/mₑ)/dₑ} represents the mechanical quality factor of the structure. For this reason, Q>1 in systems with low damping amount. The frequency domain graph of the bridge structure is shown in FIG. 4. As can be seen from the graph in FIG. 4, there is a finite displacement in the part between the direct current (I_{D}) and the resonance frequency. While the switching function is fulfilled as long as the magnetic field drive force controlled by the tuning current is below the resonance frequency of the bridge, it is damped by a low-amplitude displacement due to changes in the magnetic field drive force above the resonance frequency.

The dynamic change in the detuning signal (A) of the receiver coil is determined by Equation 12.

$${t}_{r} = \frac{1}{{ω}_{m} \sqrt{1 - \frac{1}{4 {Q}^{2}}}} {tan}^{- 1} ( 2 Q \sqrt{1 - \frac{1}{4 {Q}^{2}}} ) \qquad Equation 12$$

1. Micro electro-mechanical system (MEMS) based electro-optical magnetic resonance imaging (MRI) coil detuner, comprising:
a light source that enables optical production of a detuning signal;
a fibre optic cable which enables the optical detuning signal coming from the light source to be fibre optically transmitted via fibre optic medium;
a photo sensor which enables the conversion of the optical detuning signal from the fibre optic cable into electric current and has the photo sensor short circuit current transmitted from a cathode to an anode in case of a low ohmic connection between anode-cathode terminals;
a radiofrequency coil which transfers a direct current (DC) (I_{D}) component of the photodetector short circuit current to the detuning circuit mechanism and distinguishes high frequency components in the photodetector short circuit current;
a tuning coil which detunes the radiofrequency coil when connected to a tuning capacitor the tuning capacitor detuning the radiofrequency coil when connected to the tuning coil;
a conductive micro-electromechanical system switch common fixed lower electrode, which is connected to the tuning capacitor and ensures that the bridge is short-circuited by activating the MEMS switch bridge;
a conductive and movable first micro-electromechanical system switch movable upper electrode, which is connected to the tuning coil and ensures that the micro-electromechanical system switch common fixed lower electrode is short-circuited by activating the MEMS switch bridge;
a conductive and movable second micro-electromechanical system switch movable upper electrode, which is connected to the tuning coil and ensures that the micro-electromechanical system switch common fixed lower electrode is short-circuited by activating the MEMS switch bridge;
a conductive and movable third micro-electromechanical system switch movable right electrode, which is connected to the tuning coil and ensures that the fourth micro-electromechanical system switch fixed left electrode is short-circuited by activating the MEMS switch bridge;
a conductive fourth micro-electromechanical system switch fixed left electrode, which is connected to the tuning capacitor and ensures that the third micro-electromechanical system switch movable right electrode is short-circuited by activating the MEMS switch bridge;
a first node and a second node, which provide electrical connection of the MRI coil terminal and the MEMS-based electro-optical MRI coil detuner; and
an insulating substrate on which the first microelectromechanical system switch movable upper electrode, the second micro-electromechanical system switch movable upper electrode, the third micro-electromechanical system switch movable right electrode, micro-electromechanical system switch common fixed lower electrode and the fourth microelectromechanical system switch fixed left electrode are placed.

2. Micro electro-mechanical system (MEMS) based electro-optical magnetic resonance imaging (MRI) coil detuner according to claim 1, wherein the first micro-electromechanical system switch movable upper electrode, the second micro-electromechanical system switch movable upper electrode, the third micro-electromechanical system switch movable right electrode, the micro-electromechanical system switch common fixed lower electrode and the fourth micro-electromechanical system switch fixed left electrode form the radiofrequency MEMS bridge.

3. Micro electro-mechanical system (MEMS) based electro-optical magnetic resonance imaging (MRI) coil detuner according to claim 1, wherein the micro-electromechanical system switch common fixed lower electrode forms the bottom plate of the radiofrequency MEMS bridge.

4. Micro electro-mechanical system (MEMS) based electro-optical magnetic resonance imaging (MRI) coil detuner according to claim 1, wherein the first micro-electromechanical system switch movable upper electrode forms the upper plate of the radiofrequency MEMS bridge.

5. Micro electro-mechanical system (MEMS) based electro-optical magnetic resonance imaging (MRI) coil detuner according to claim 1, wherein the second micro-electromechanical system switch movable upper electrode forms the side plate of the radiofrequency MEMS bridge and is connected to the end of the first micro-electromechanical system switch movable upper electrode.

6. Micro electro-mechanical system (MEMS) based electro-optical magnetic resonance imaging (MRI) coil detuner according to claim 1, wherein the third micro-electromechanical system switch movable right electrode forms the side plate of the radiofrequency MEMS bridge and is connected to the second micro-electromechanical system switch movable upper electrode with the connection cable.

7. Micro electro-mechanical system (MEMS) based electro-optical magnetic resonance imaging (MRI) coil detuner according to claim 1, wherein the fourth micro-electromechanical system switch fixed left electrode forms the side plate of the radiofrequency MEMS bridge and is located parallel to the first micro-electromechanical system switch movable upper electrode.
